(19) United States
(12) Patent Application Publication
(10) Pub. No.: US 2011/0214724 A1
(43) Pub. Date: Sep. 8, 2011

(54) SOLAR CELL

(75) Inventor: Kyoung-Jin SEO, Suwon-si (KR)

(73) Assignee: SAMSUNG ELECTRONICS CO., LTD., Suwon-si (KR)

(21) Appl. No.: 12/903,439

(22) Filed: Oct. 13, 2010

(30) Foreign Application Priority Data
Mar. 4, 2010 (KR) 10-2010-0019506

(51) Int. Cl. H01L 31/0216; H01L 31/06

(52) U.S. Cl. 136/255; 136/256

(57) ABSTRACT

A solar cell includes a semiconductor substrate including a first conductivity type region; a semiconductor layer disposed on a first surface of the semiconductor substrate and including second conductivity type impurities; a first mask film disposed on a second surface of the semiconductor substrate; a second mask film disposed on the first mask film; and an electrode disposed on the second mask film.

This application claims priority to Korean Patent Application No. 10-2010-0019506, filed on Mar. 4, 2010, and all the benefits accruing therefrom under 35U.S.C. §119, the content of which in its entirety is herein incorporated by reference.

### BACKGROUND OF THE INVENTION

(1) Field of the Invention

The present invention generally relates to a solar cell.

(2) Description of the Related Art

A solar cell uses photonic energy, i.e., solar energy, to produce electricity. Specifically, photonic energy, i.e., solar energy, input to a solar cell generates electron-hole pairs (“EHPs”) in N-type and P-type semiconductors of the solar cell, and an electric field created across a P-N junction causes electrons to move to the N-type semiconductor and holes to move to the P-type semiconductor, respectively. As a result, electricity is produced within the solar cell.

A solar cell typically includes a front electrode and a rear electrode. The rear electrode is disposed on a rear surface of a semiconductor substrate and may include an aluminum electrode. A silicon nitride film is typically disposed between the rear electrode and the semiconductor substrate. The silicon nitride film is a type of an insulating film commonly applied to semiconductor substrates.

A silicon nitride film disposed on the semiconductor substrate by a conventional process has poor adhesion to an aluminum electrode. In particular, if openings are formed by removing parts of the silicon nitride film to form electrode extension regions, adhesion between the silicon nitride film and the aluminum electrode further deteriorates. Therefore, a solar cell which has substantially improved adhesion between a silicon nitride film and an aluminum electrode is needed.

### BRIEF SUMMARY OF THE INVENTION

Aspects of the present invention provide a solar cell including increased adhesion of an electrode to a silicon nitride film.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present invention, there is provided an exemplary embodiment of a solar cell including a semiconductor substrate including a first conductivity type region; a semiconductor layer disposed on a first surface of the semiconductor substrate, wherein the semiconductor layer includes second conductivity type impurities; a first mask film disposed on a second surface of the semiconductor substrate; a second mask film disposed on the first mask film; and an electrode disposed on the second mask film.

According to an aspect of the present invention, there is provided an exemplary embodiment of a solar cell including a semiconductor substrate including a first conductivity type region; a semiconductor layer disposed on a first surface of the semiconductor substrate, wherein the semiconductor layer includes a second conductivity type region; a mask film disposed on a second surface of the semiconductor substrate and including silicon nitride; and an electrode disposed on the mask film, wherein the mask film includes an upper region which contacts the semiconductor substrate and a lower region which contacts the electrode, wherein silicon content of the lower region of the mask film is greater than silicon content of the upper region of the mask film.

According to an aspect of the present invention, there is provided an exemplary embodiment of a solar cell including a semiconductor substrate including a first conductivity type region; a semiconductor layer disposed on a first surface of the semiconductor substrate, wherein the semiconductor layer includes a second conductivity type region; a mask film disposed on a second surface of the semiconductor substrate, wherein the mask film includes silicon nitride; and an electrode disposed on the mask film, wherein silicon content of the mask film increases from an interface between the mask film and the semiconductor substrate to an interface between the mask film and the electrode.

According to another aspect of the present invention, there is provided an another exemplary embodiment of a solar cell including a semiconductor substrate including a first conductivity type region; a semiconductor layer disposed on a first surface of the semiconductor substrate, wherein the semiconductor layer includes a second conductivity type region; a mask film disposed on a second surface of the semiconductor substrate; and an electrode disposed on the mask film, wherein the mask film has a refractive index of 2.3 or more.

### BRIEF DESCRIPTION OF THE DRAWINGS

The above and other aspects of the present invention will become more apparent by describing in detail exemplary embodiments thereof with reference to the attached drawings, in which:

FIG. 1 is a cross-sectional view of an exemplary embodiment of a solar cell of the present invention;

FIGS. 2 through 8 are cross-sectional views of other exemplary embodiments of solar cells of the present invention;

FIG. 9A is a surface photograph showing adhesion of an electrode to a silicon nitride film in a comparative embodiment of a solar cell; and

FIG. 9B is a surface photograph showing adhesion of an electrode to a silicon nitride film in an exemplary embodiment of a solar cell according to the present invention.

### DETAILED DESCRIPTION OF THE INVENTION

Advantages and features of the present invention and methods of accomplishing the same may be understood more readily by reference to the following detailed description of exemplary embodiments and the accompanying drawings.

The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims.

Spatially relative terms, such as “below,” “beneath,” “lower,” “above,” “upper,” and the like, may be used herein for ease of description to describe one device or element's relationship to another device(s) or element(s) as illustrated in the drawings. It will be understood that the spatially relative terms are intended to encompass different orientations of the device in use or operation in addition to the orientation depicted in the drawings. For example, if the device in the figures is turned over, elements described as “below” or “beneath” other elements or features would then be oriented “above” the other elements or features. Thus, the exemplary term “below” can encompass both an orientation of above and below. The device may be otherwise oriented and the spatially relative descriptors used herein interpreted accordingly.

As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

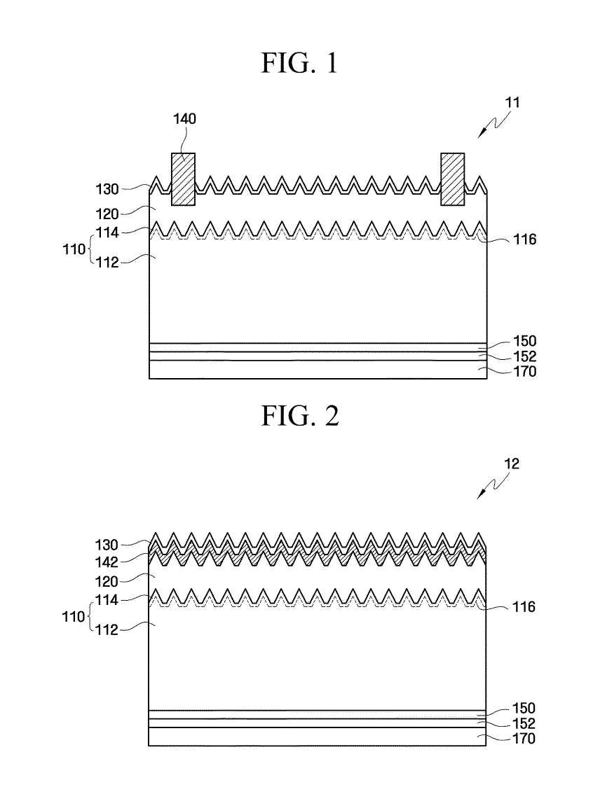

Hereinafter, exemplary embodiments of the present invention will be further described with reference to the attached drawings. FIG. 1 is a cross-sectional view showing an exemplary embodiment of a solar cell 11 according to the present invention.

Referring to FIG. 1, an exemplary embodiment of the solar cell 11 includes a semiconductor substrate 110. In one exemplary embodiment, the semiconductor substrate 110 may be a silicon substrate. Specifically, exemplary embodiments include configurations wherein the semiconductor substrate 110 may be a silicon wafer which includes crystalline silicon.

The semiconductor substrate 110 has a first surface and a second surface. The first surface of the semiconductor substrate 110 may be a front surface which receives sunlight. Accordingly, the second surface of the semiconductor substrate 110 may be a rear surface which is disposed substantially opposite to the first surface of the semiconductor substrate 110.

In some exemplary embodiments, the first surface of the semiconductor substrate 110 may have an uneven structure. The uneven structure increases a surface area of the first surface of the semiconductor substrate 110. Some uneven structures not only increase the surface area but also contribute to an absorption rate of incident light. Exemplary embodiments of the uneven structures mentioned above include a pyramid pattern and a reverse pyramid pattern, for example. However, the present invention is not limited thereto, and the uneven structure may also be an array of triangular pyramids, poly pyramids (e.g., pentagonal or polygonal pyramids), or cones, or other similar shapes, for example. Alternatively, the uneven structure may be an array of poly prisms or cylinders, or other similar shapes, for example. Also, various other uneven structures that increase the surface area and/or the light absorption rate may be employed as a shape of the first surface of the semiconductor substrate 110.

The space between the first and second surfaces of the semiconductor substrate 110 may be divided into a first region 112 including a first conductivity type and a second region 114 including a second conductivity type different from the first conductivity type. The first region 112 may be a region adjacent to the second surface of the semiconductor substrate 110, and the second region 114 may be a region adjacent to the first surface of the semiconductor substrate 110. In the exemplary embodiment illustrated in FIG. 1, the second region 114 is disposed on the first region 112.

The first conductivity type of the first region 112 may be determined by a conductivity type of the semiconductor substrate 110. In an exemplary embodiment, wherein the semiconductor substrate 110 is a P-type substrate, the first conductivity type may be a P type conductivity, for example. The first conductivity type of the first region 112 may result from impurities (also referred to as “dopants”) of the first conductivity type in the first region 112. The impurities of the first conductivity type may contain a chemical element which belongs to group III of a periodic table, such as boron (B), aluminum (Al), gallium (Ga), etc., for example.

The second conductivity type of the second region 114 may be different from the first conductivity type as mentioned above. In an exemplary embodiment, wherein the first conductivity type is a P type, the second conductivity type may be an N type conductivity, for example. The second conductivity type of the second region 114 may result from doping or diffusing second conductivity type impurity ions therein.

In some exemplary embodiments, a semiconductor layer 120 is doped with the second conductivity type impurity ions. In the process of doping the second conductivity type impurity ions into the semiconductor layer 120, some of the second conductivity type impurity ions may also be doped into the semiconductor substrate 110. In an exemplary embodiment, even when the second conductivity type impurity ions are doped only into the semiconductor layer 120, some of the second conductivity type impurity ions may diffuse to a region of the semiconductor substrate 110, which is adjacent to the semiconductor layer 120. The impurity ions diffused into the semiconductor substrate 110 in this way may form the second region 114 of the second conductivity type in an upper part of the semiconductor substrate 110.

The impurities of the second conductivity type may include a chemical element which belongs to group V of the periodic table, such as phosphorus (P), arsenic (As), etc., for example. A concentration of impurity ions of the second conductivity type in the second region 114 may be approximately 10¹⁹˜10²¹ ions per centimeter cubed (/cm³).

In some embodiments, a concentration of impurity ions of the second conductivity type in the second region 114 may be lower than a concentration of impurity ions of the second conductivity type in the semiconductor layer 120. Even within the second region 114, the concentration of impurity ions of the second conductivity type may vary according to a distance to the semiconductor substrate 120. In some embodiments, the second region 114 may have a gradient concentration distribution in which the concentration of the second conductivity type impurity ions is gradually reduced as the distance from the semiconductor layer 120 increases, i.e., as the depth from the first surface of the semiconductor substrate 110 increases.

The semiconductor layer 120 is disposed on the first surface of the semiconductor substrate 110. The semiconductor layer 120 may be conformably disposed on the first surface of the semiconductor substrate 110. That is, a surface of the semiconductor layer 120 may have substantially a same shape as the first surface of the semiconductor substrate 110.

In one exemplary embodiment, the semiconductor layer 120 may be an amorphous silicon layer heavily doped with the second conductivity type impurity ions. The semiconductor layer 120 may have a gradient concentration distribution in which the concentration of impurity ions gradually increases as a distance from the semiconductor substrate 112 increases.

A heterogeneous junction may be formed at an interface between the semiconductor layer 120 which includes amorphous silicon of the second conductivity type and the semiconductor substrate 110 which includes crystalline silicon of the first conductivity type. Accordingly, a wider spectrum of incident light energy may be received.

In an exemplary embodiment, the second region 114 of the semiconductor substrate 110 may be omitted. In such an exemplary embodiment, a PN junction 116 may be formed at the interface between the semiconductor layer 120 and the semiconductor substrate 110.

An anti-reflective film 130 may be disposed on the semiconductor layer 120. In such an exemplary embodiment, when an optical thickness of the anti-reflective film 130 is equal to one quarter of a wavelength of the incident light, the anti-reflective film 130 may be a non-reflective coating and may further reduce reflectivity of incident light. To reduce thickness errors caused by a single film, the anti-reflective film 130 may be disposed as a double film or may include even more layers. The anti-reflective film 130 may be a silicon oxide film, a silicon nitride film, or a laminate thereof, for example. Since the anti-reflective film 130 is disposed on a front surface, i.e., light-receiving surface of the solar cell 11, the anti-reflective film 130 may function to protect the solar cell 11. In an exemplary embodiment, the anti-reflective film 130 may be omitted.

First electrodes 140 are disposed on the reflection preventing film 130. Since the first electrodes 140 are disposed on a front side of the solar cell 11, the first electrodes 140 may also be referred as front electrodes. The first electrodes 140 having a predetermined width may be arranged in a lattice or zigzag form.

A portion of each of the first electrodes 140 may penetrate the anti-reflective film 130 and extend into the semiconductor layer 120. To this end, electrode trenches or grooves may be formed in the anti-reflective film 130 and/or the semiconductor layer 120. The first electrodes 140 may include silver (Ag), aluminum (Al), copper (Cu), Nickel (Ni), tungsten (W), titanium (Ti), titanium tungsten (TiN), tungsten nitride (WN), a metal silicon film, other materials with similar characteristics, or a laminate thereof. In a certain exemplary embodiments, the first electrodes 140 may include an Ag film.

A first mask film 150 is disposed on the second surface of the semiconductor substrate 110 and a second mask film 152 is disposed on the first mask film 150. In addition, a second electrode 170 is disposed on the second mask film 152. Since the second electrode 170 is disposed on a lower part of the solar cell 11, it may be referred to as a rear electrode. Like the first electrodes 140, the second electrode 170 may include Ag, Al, Cu, Ni, W, Ti, TiN, WN, a metal silicon film, other materials with similar characteristics, or a laminate thereof. In a certain exemplary embodiment, the second electrode 170 may include an Al film. Here, the Al film may be formed by baking Al paste, for example.

Each of the first mask film 150 and the second mask film 152 may be an insulating film that contains silicon. The first mask film 150 may be a SiaXb film, and the second mask film 152 may be a SicXd film, for example. Here, X may be any one of nitrogen (N), carbon (C), and oxygen (O), for example, but is not limited thereto. The following description is based on the assumption that X is N, for example.

In an exemplary embodiment, when X is N, both the first mask film 150 and the second mask film 152 are silicon nitride films. Here, a and b indicate a ratio of Si to N in the first mask film 150, and c and d indicate a ratio of Si to N in the second mask film 152.

A ratio of Si to N in a typical silicon nitride film is about 3:4. However, it was experimentally proved that a Si3N4 film has good adhesion to the semiconductor substrate 110 but relatively poor adhesion to a material which forms the second electrode 170, for example, Al. Therefore, if the Si3N4 film is used for both the first and second mask films 150 and 152, the adhesion between the first and second mask films 150 and 152 and the second electrode 170 is reduced. However, it was experimentally proved that if the first and second mask films 150 and 152 contain a relatively increased Si content in a silicon nitride film, the adhesion of the first and second mask films 150 and 152 to aluminum increases.

Thus, even when both the first and second mask films 150 and 152 are formed using silicon nitride films, it may be advantageous in terms of adhesion between the second mask film 152 and the second electrode 170 to increase the Si content of the second mask film 152 adjacent to the second electrode 170. That is, if the first mask film 150 is a SiₐN_{b} film and if the second mask film 152 is a Si_{c}N_{d} film, the adhesion between the second mask film 152 and the second electrode 170 may be increased by making c/d greater than a/b. As described above, the first mask film 150 has good adhesion to the semiconductor substrate 110. In addition, adhesion between the first mask film 150 and second mask film 152 is strong because the first mask film 150 and second mask film 152 contain a similar material. Accordingly, good adhesion between the second mask film 152 and the second electrode 170 results in good adhesion between the second electrode 170 and the semiconductor substrate 110.

Si content can be adjusted by a plasma-enhanced chemical vapor deposition (“PECVD”) process. If a film formed by the PECVD process is defined as a “PECVD film”, the second mask film 152 may be a PECVD film. Furthermore, exemplary embodiments include configurations wherein the first mask film 150 may be a PECVD film.

Si content affects a refractive index of a film. A greater content of Si in a silicon nitride film increases the refractive index of the silicon nitride film. Thus, the Si content of a silicon nitride film may also be defined as a refractive index of the silicon nitride film. If a refractive index of the first mask film 150 is n₁ and if a refractive index of the second mask film 152 is n₂, then n₂ is greater than n₁, i.e., n₂>n₁. When a ratio n₂/n₁ is 1.15 or more, better adhesion can be achieved between the second mask film 152 and the second electrode 170. In an exemplary embodiment, n₂ may be 2.3 or more.

Hereinafter, other exemplary embodiments of the present invention will be described. In the following exemplary embodiments, elements substantially identical to those of the previous exemplary embodiment are indicated by same reference numerals, and thus their description will be omitted or simplified.

FIG. 2 is a cross-sectional view of an exemplary embodiment of a solar cell 12. Referring to FIG. 2, the exemplary embodiment of the solar cell 12 is substantially the same as the exemplary embodiment of the solar cell 11 shown in FIG. 1 except that a first electrode 142 is disposed on an entire surface of a semiconductor layer 120 of the solar cell 12.

The first electrode 142 may be disposed on the semiconductor layer 120. The first electrode 142 may have an uneven structure of a surface thereof. Since the first electrode 142 is disposed on the entire surface of the semiconductor layer 120, the first electrode 142 may include a transparent conductive material to receive light through the entire surface of the semiconductor layer 120. Examples of transparent conductive materials applicable to the first electrode 142 may include indium tin oxide (“ITO”) and aluminum-doped zinc oxide (“AZO”). An anti-reflective film 130 may be disposed on the first electrode 142.

The exemplary embodiment of the solar cell 12 is substantially identical to the embodiment of the solar cell 11 shown in FIG. 1 in that a first mask film 150 and a second mask film 152 are interposed between a second surface of a semiconductor substrate 110 and a second electrode 170 and that the second mask film 152 has a composition which ensures superior adhesion to the second electrode 170. Accordingly, the adhesion between the second electrode 170 and the semiconductor substrate 110 may be substantially improved.

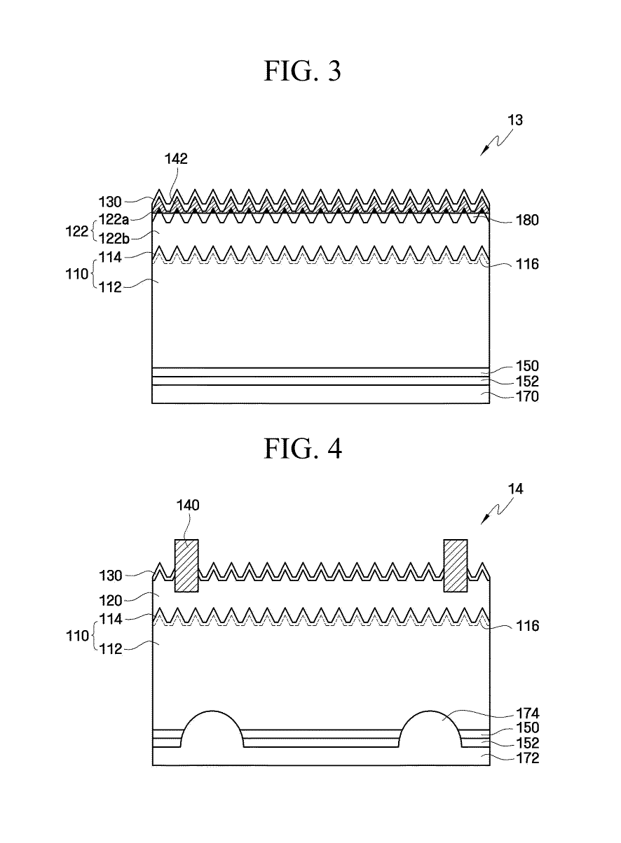

FIG. 3 is a cross-sectional view of an exemplary embodiment of a solar cell 13. Referring to FIG. 3, the exemplary embodiment of the solar cell 13 is substantially the same as the embodiment of the solar cell 12 shown in FIG. 2 except that a semiconductor layer 122 is divided into a first impurity region 122b and a second impurity region 122a according to the concentration of impurities and that an insulating layer 180 is disposed between a first electrode 142 and a front surface, i.e., a light-receiving surface, of the semiconductor layer 122.

The insulating layer 180 fills lower parts of depressed regions of the front surface of the semiconductor layer 122 and exposes upper parts of raised regions of the front surface of the semiconductor layer 122. The insulating layer 180 may prevent recombination of electron-hole pairs (“EHP”) formed by light, e.g., sunlight. The insulating layer 180 may include a material with high light transmittance in order not to reduce the amount of light that passes therethrough. The light transmittance of the insulating layer 180 may be about 85 percent (%) to about 95%, for example. Materials having the above properties include polyimide-based materials, acrylate-based materials, imide-siloxane polymers, amide-siloxane compounds, polyorganosilsesquioxane ([RSiO3/2]n), polymethylsilsesquioxane, and polysilsesquioxane, for example.

The second impurity region 122a is disposed in the upper parts of the raised regions of the front surface of the semiconductor layer 122 which are exposed through the insulating layer 180, and the first impurity region 122b is disposed under the second impurity region 122a.

Both of the first impurity region 122b and the second impurity region 122a contain second conductivity type impurity ions. However, they differ in that the concentration of impurity ions in the second impurity region 122a is higher than concentration of impurity ions in the first impurity region 122b. The concentration of impurity ions in the first impurity region 122b may be substantially equal to concentration of impurity ions in the semiconductor layer 120 shown in FIG. 2.

The first electrode 142 directly contacts the second impurity region 122a but does not directly contact the first impurity region 122b. That is, the second impurity region 122a is interposed between the first electrode 142 and the first impurity region 122b. Since the second impurity region 122a has a relatively high concentration of impurity ions, it may function as an ohmic contact layer, thereby reducing ohmic contact resistance.

The exemplary embodiment of the solar cell 13 is substantially identical to the embodiment of FIG. 1 in that a first mask film 150 and a second mask film 152 are interposed between a second surface of a semiconductor substrate 110 and a second electrode 170 and that the second mask film 152 has a composition which ensures superior adhesion to the second electrode 170. Accordingly, the adhesion between the second electrode 170 and the semiconductor substrate 110 may be improved.

FIG. 4 is a cross-sectional view of an exemplary embodiment of a solar cell 14. Referring to FIG. 4, the exemplary embodiment of the solar cell 14 is different from the exemplary embodiment of FIG. 1 in that electrode extension regions 174 extend into a semiconductor substrate 110.

The electrode extension regions 174 are electrically connected to a second electrode 172. When the second electrode 172 includes a metal film, the electrode extension regions 174 may be metal silicide regions. In an exemplary embodiment, when the second electrode 172 includes an Al film, the electrode extension regions 174 may be Al silicide regions. The electrode extension regions 174 may function as a contact between the second electrode 172 and the semiconductor substrate 110. Openings are formed in a first mask film 150 and a second mask film 152 to form the electrode extension regions 174.

The openings in the first mask film 150 and the second mask film 152 may deteriorate an adhesion between the semiconductor substrate 110 and the second electrode 172. However, like the second mask film 152 according to the previously described exemplary embodiment of FIG. 1, the second mask film 152 according to the current exemplary embodiment has a composition which ensures superior adhesion to the second electrode 172. Thus, the adhesion between the second electrode 172 and the semiconductor substrate 110 may be substantially increased.

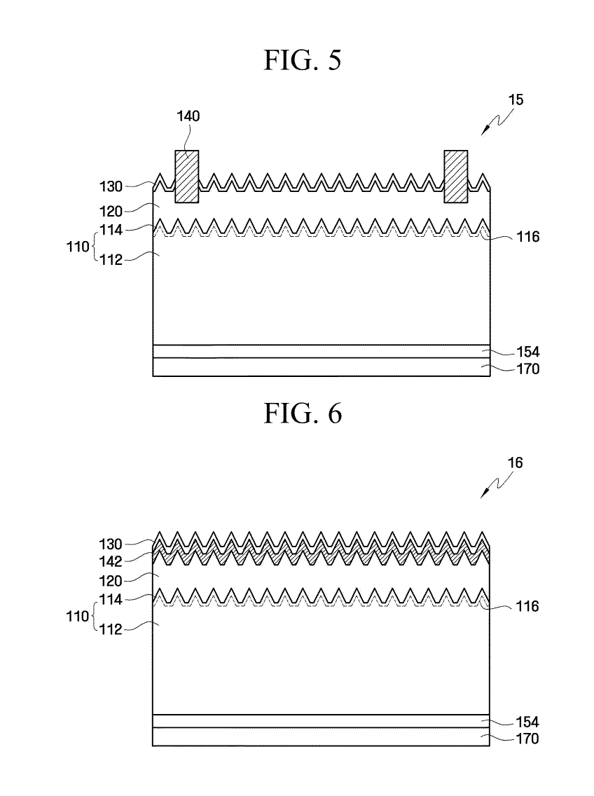

FIG. 5 is a cross-sectional view of an exemplary embodiment of a solar cell 15. Referring to FIG. 5, the exemplary embodiment of the solar cell 15 is different from the exemplary embodiment of FIG. 1 in that a mask film 154 is disposed as a single film.

While the mask film 154 disposed as a single film does not include an interface therein, an upper region of the mask film 154 has substantially the same composition as the first mask film 150 of FIG. 1, and a lower region of the mask film 154 has substantially a same composition as the second mask film 152 of FIG. 1. Accordingly, the current exemplary embodiment can have substantially the same improvement of adhesion as the exemplary embodiment of FIG. 1.

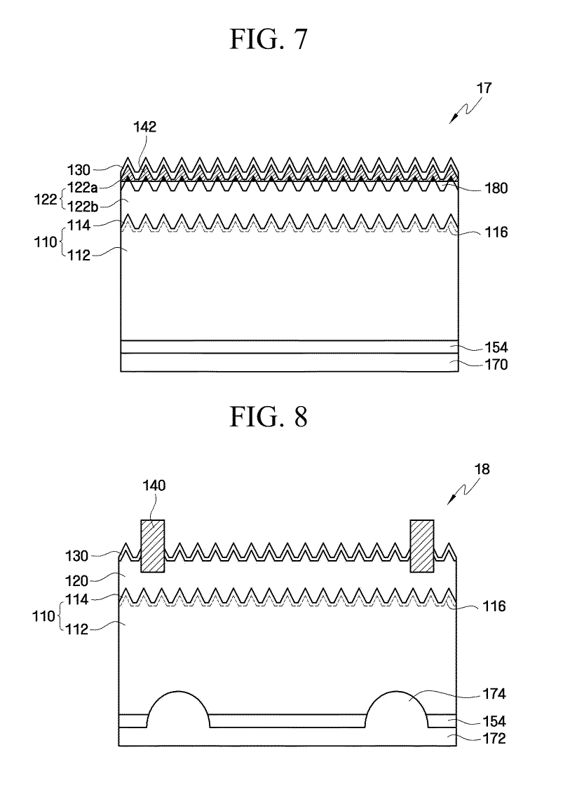

FIGS. 6 through 8 are cross-sectional views of exemplary embodiments of solar cells 16 through 18. The solar cells 16 through 18 have substantially the same structures as the solar cells 12 through 14 of FIGS. 2 through 4, respectively, except that the mask film 154 of FIG. 5 is employed in place of a first mask film 150 and a second mask film 152. Therefore, it can be understood that the currently described exemplary embodiments have substantially the same improvement of adhesion as the embodiment of FIG. 5.

Various other exemplary embodiments of the present invention will now be described without reference to drawings.

Some exemplary embodiments of the present invention have substantially the same structures as exemplary embodiments of FIGS. 5 through 8 except that a mask film has a gradient concentration distribution in which Si content increases from an interface between the mask film and a semiconductor substrate to an interface between the mask film and a second electrode. In addition, a refractive index of the mask film increases from the interface between the mask film and the semiconductor substrate to the interface between the mask film and the second electrode. Since Si content in the mask film is at a maximum at the interface between the mask film and the second electrode, the adhesion between the semiconductor substrate and the second electrode may be substantially increased.

Some other exemplary embodiments of the present invention have substantially the same structures as those of FIGS. 1 through 4 except that a second mask film has a gradient concentration distribution in which Si content increases from an interface between the second mask film and a first mask film to an interface between the second mask film and a second electrode.

Some other exemplary embodiments of the present invention have substantially the same structures as those of FIGS. 5 through 8 except that a mask film has substantially a same composition as the second mask film 152 of FIGS. 1 through 4. The exemplary embodiments of the mask film may be a Si-rich silicon nitride film having a refractive index of about 2.3 or more. In one exemplary embodiment, the silicon nitride film may be a PECVD film.

Hereinafter, the present invention will be further described by way of examples.

### Inventive Example 1

A first silicon nitride film was formed on a semiconductor substrate by a PECVD process. Power and the amount of reactive gas used in the PECVD process are provided in Table 1 below.

TABLE 1

| | |
|---|---|
| Power (W) | 690 |
| SiH4 (sccm) | 100 |
| NH3 (sccm) | 45 |
| N2 (sccm) | 4300 |

Then, a second silicon nitride film was formed on the first silicon nitride film by changing processing conditions to increase Si content. Power and the amount of reactive gas used in a PECVD process which was performed to form the second silicon nitride film are provided in Table 2 below.

TABLE 2

| | |
|---|---|
| Power (W) | 550 |
| SiH4 (sccm) | 340 |
| NH3 (sccm) | 10 |
| N2 (sccm) | 4000 |

### Comparative Example 1

A silicon nitride film was formed on a semiconductor substrate by a PECVD process. Power and the amount of reactive gas used in the PECVD process are provided in Table 3 below.

TABLE 3

| | |
|---|---|
| Power (W) | 690 |
| SiH4 (sccm) | 100 |
| NH3 (sccm) | 45 |
| N2 (sccm) | 4300 |

### Experiment Example 1

### Refractive Index

Refractive indices of the silicon nitride films formed according to inventive example 1 and comparative example 1 and a refractive index of crystalline silicon were measured. The first silicon nitride film according to inventive example 1 and the silicon nitride film according to comparative example 1 were formed under the same processing conditions. Accordingly, both of the first silicon nitride film according to inventive example 1 and the silicon nitride film according to comparative example 1 had a refractive index of 1.98. However, the second silicon nitride film formed according to inventive example 1 had a refractive index of 2.45 while the measured refractive index of the crystalline silicon, which contains only silicon, was 3.41. It can be understood that a greater content of silicon relative to nitrogen results in a higher refractive index.

### Inventive Example 2

Aluminum paste was deposited on the second silicon nitride film formed according to inventive example 1 and baked to form an aluminum electrode.

### Comparative Example 2

Aluminum paste was deposited on the silicon nitride film formed according to comparative example 1 and baked to form an aluminum electrode.

### Experiment Example 2

### Adhesion

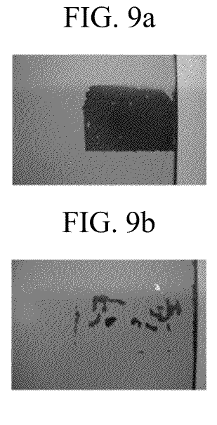

Surfaces of structures formed according to inventive example 2 and comparative example 2 were observed. The results are shown in FIGS. 9A and 9B.

FIG. 9A is a photograph of a surface of a semiconductor device fabricated according to the comparative example 2. FIG. 9B is a photograph of a surface of a semiconductor device fabricated according to the inventive example 2.

Referring to FIG. 9A, the electrode on the silicon nitride film disposed according to comparative 2 was partially removed. However, referring to FIG. 9B, the electrode disposed on the relatively Si-rich second silicon nitride film was not removed or the removal was greatly decreased. Accordingly, it can be understood that inventive example 2 ensures better adhesion of an electrode to a silicon nitride film than comparative example 2.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A solar cell comprising:
a semiconductor substrate which includes a first conductivity type region;
a semiconductor layer disposed on a first surface of the semiconductor substrate, wherein the semiconductor layer includes impurities having a second conductivity type different from the first conductivity type;
a first mask film disposed on a second surface of the semiconductor substrate;
a second mask film disposed on the first mask film; and
an electrode disposed on the second mask film.

2. The solar cell of claim 1, wherein the first mask film includes SiₐX_{b}, and the second mask film includes Si_{c}X_{d}, wherein X is one of nitrogen, carbon and oxygen, and a ratio of c/d is greater than ratio of a/b.

3. The solar cell of claim 2, wherein X is nitrogen and the electrode comprises aluminum.

4. The solar cell of claim 3, wherein the second mask film is a plasma-enhanced chemical vapor deposition film.

5. The solar cell of claim 1, further comprising electrode extension regions which extend from the electrode into the semiconductor substrate.

6. The solar cell of claim 1, wherein a refractive index of the first mask film is n₁, and a refractive index of the second mask film is n₂, wherein n₂/n₁ is 1.15 or more.

7. The solar cell of claim 6, wherein n₂ is 2.3 or more.

8. The solar cell of claim 1, wherein the semiconductor substrate comprises a crystalline silicon substrate, and the semiconductor layer comprises an amorphous silicon layer.

9. The solar cell of claim 8, further comprising a second conductivity type region containing impurities having the second conductivity type, wherein the second conductivity type region is disposed between the first conductivity type region and the semiconductor layer, and a concentration of the impurities having the second conductivity type in the second conductivity type region is lower than a concentration of the impurities having the second conductivity type in the semiconductor layer.

10. The solar cell of claim 1, wherein the first surface of the semiconductor substrate has an uneven structure.

11. A solar cell comprising:
a semiconductor substrate which includes a first conductivity type region;
a semiconductor layer disposed on a first surface of the semiconductor substrate and including a second conductivity type region wherein the second conductivity type region has a different conductivity type than the first conductivity type region;
a mask film disposed on a second surface of the semiconductor substrate and comprising silicon nitride; and
an electrode disposed on the mask film,
wherein the mask film has an upper region which contacts the semiconductor substrate and a lower region which contacts the electrode, wherein the lower region of the mask film has a greater silicon content than the upper region of the mask film.

12. The solar cell of claim 11, wherein the electrode comprises aluminum.

13. The solar cell of claim 12, wherein the semiconductor substrate is a crystalline silicon substrate, and further comprising aluminum silicide regions which extend from the electrode to the semiconductor substrate.

14. A solar cell comprising:
a semiconductor substrate including a first conductivity type region;
a semiconductor layer disposed on a first surface of the semiconductor substrate and including a second conductivity type region;
a mask film disposed on a second surface of the semiconductor substrate and containing silicon nitride; and
an electrode disposed on the mask film,
wherein the silicon content of the mask film increases with distance from an interface between the mask film and the semiconductor substrate to an interface between the mask film and the electrode.

15. The solar cell of claim 14, wherein the electrode comprises aluminum.

16. The solar cell of claim 15, wherein the semiconductor substrate comprises a crystalline silicon substrate, and the semiconductor substrate further comprises aluminum silicide regions which extend from the electrode to the semiconductor substrate.

17. A solar cell comprising:
a semiconductor substrate including a first conductivity type region;
a semiconductor layer disposed on a first surface of the semiconductor substrate and including a second conductivity type region;
a mask film disposed on a second surface of the semiconductor substrate, wherein the mask film has a refractive index equal to or greater than about 2.3; and
an electrode disposed on the mask film.

18. The solar cell of claim 17, wherein the electrode comprises aluminum.

19. The solar cell of claim 18, wherein the semiconductor substrate comprises a crystalline silicon substrate, and the semiconductor substrate further comprises aluminum silicide regions which extend from the electrode to the semiconductor substrate.
